(19) United States
(12) Patent Application Publication
(10) Pub. No.: US 2025/0183141 A1
(43) Pub. Date: Jun. 5, 2025

(54) DISPLAY DEVICE

(71) Applicant: LG DISPLAY CO., LTD., Seoul (KR)

(72) Inventor: Buhui LEE, Paju-si (KR)

(73) Assignee: LG DISPLAY CO., LTD., Seoul (KR)

(21) Appl. No.: 18/746,781

(22) Filed: Jun. 18, 2024

(30) Foreign Application Priority Data
Nov. 30, 2023 (KR) 10-2023-0170731

(51) Int. Cl. H01L 23/498; H10K 59/131; H10K 59/80; H10K 59/90; H10K 102/00

(52) U.S. Cl. CPC H01L 23/49822; H01L 23/4985; H10K 59/131; H10K 59/80; H10K 59/90; H10K 2102/311

(57) ABSTRACT

A display device includes a display panel including a display area, a first part positioned around the display area and including a first non-display area, and second parts disposed in a second non-display area positioned outside the first non-display area, and a bridge part disposed between adjacent second parts, wherein the second parts are spaced apart from each other in a first direction, each of the second parts protrudes from the first part in a second direction intersecting the first direction, and the bridge part physically connects the adjacent second parts.

### CROSS-REFERENCE TO RELATED APPLICATION

The present application claims priority to Korean Patent Application No. 10-2023-0170731, filed on Nov. 30, 2023, which is hereby incorporated by reference in its entirety.

### BACKGROUND

### Field of the Disclosure

The present disclosure relates to a display device.

### Description of the Background

As the information society develops, various demands for display devices for displaying images are increasing, and various types of display devices such as liquid crystal displays (LCDs) and organic light emitting diode (OLED) displays are utilized.

Among the display devices, there is an advantage in that the OLED displays as the self-luminous types have superior viewing angles and contrast ratios than the LCDs, and are lighter and thinner and have low power consumption because they do not require a separate backlight. In addition, there is an advantage in that the OLED displays may drive at a low direct current voltage, have a fast response speed, and especially low manufacturing costs.

Meanwhile, research on many structures for reducing bezels of display devices is being conducted.

### SUMMARY

The present disclosure is to provide a display device with a reduced bezel.

The present disclosure is also to provide a display device in which curvatures between bending areas are uniform.

The present disclosure is also to provide a display device with improved attachment deviation between a printed circuit film and/or a circuit board.

The present disclosure is not limited to the above-described, and other technical advantages may be inferred from aspects below.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display panel includes a display area, a first part positioned around the display area and including a first non-display area, and second parts disposed in a second non-display area positioned outside the first non-display area, and a bridge part disposed between adjacent second parts, wherein the second parts are spaced apart from each other in a first direction, each of the second parts protrudes from the first part in a second direction intersecting the first direction, and the bridge part physically connects the adjacent second parts.

In another aspect of the present disclosure, a display device includes a display panel including a first part, and second parts protruding from the first part and including a bending area, and a bridge part disposed between adjacent second parts, wherein the second parts are spaced apart from each other in a first direction, each of the second parts protrudes from the first part in a second direction intersecting the first direction, the second part is bent in the bending area, and radii of curvature of the second parts are the same.

Detailed matters of other aspects are included in a detailed description and accompanying drawings.

The display panel of the display device according to the aspects includes a first part, and a second part protruding from the first part and including a bending area. The second part is provided with the pad area and attached to the printed circuit film. The second part may be bent in the thickness direction through the bending area of the second part, thereby reducing the bezel space of the display device.

In addition, the plurality of second parts may be provided. The plurality of second parts may be spaced apart from each other. For the medium or large-sized display device, when one second part is provided, the bending stress increases and thus the bending of the second part cannot be easy. However, since the display devices according to the aspects are provided with the plurality of second parts, it is possible to easily reduce the bezel even in the case of the medium or large-sized display device.

In addition, the display devices according to the aspects further include the bridge part connecting adjacent second parts. When the second parts are bent, the radii of curvature of the second parts may be different, and in this case, the attachment deviation between the printed circuit film attached to the pad area of the second part and the circuit board attached to the printed circuit film may occur. However, since the display devices according to the aspects may further include the bridge part connecting the adjacent second parts, even when the plurality of second parts are bent, the radii of curvature of the second parts may each be formed uniformly.

In addition, since the display devices according to the aspects have the improved attachment deviation between the printed circuit film attached to the pad area of the second part and the circuit board attached to the printed circuit film, it is possible to reduce the defect rate when the display device is manufactured. Therefore, it is possible to save the costs and achieve process optimization.

However, the effects obtainable from the present disclosure are not limited to the above-described effects, and other effects that are not mentioned will be able to be clearly understood by those skilled in the art to which the present disclosure pertains from the following description.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a plan view of a display device according to a first aspect of the present disclosure;

FIG. 2 is a cross-sectional view showing a folded state of the display device shown in FIG. 1;

FIG. 3 is an enlarged plan view of area Q1 in FIG. 1;

FIG. 4 is a cross-sectional view along line A-A′ in FIG. 3;

FIG. 5 is an enlarged plan view of area Q2 in FIG. 1;

FIG. 6 is a cross-sectional view along line B-B′ in FIG. 5;

FIG. 7 is a cross-sectional view along line C-C′ in FIG. 5;

FIG. 8 is a schematic view showing attachment deviation between printed circuit films of the display device according to the first aspect of the present disclosure;

FIG. 9 is a schematic view showing attachment deviation of a circuit board of the display device according to the first aspect of the present disclosure;

FIG. 10 is a plan view of a display device according to a second aspect of the present disclosure;

FIG. 11 is a cross-sectional view along line C-C′ in FIG. 10; and

FIG. 12 is a cross-sectional view along line D-D′ in FIG. 10.

### DETAILED DESCRIPTION

Hereinafter, aspects will be described with reference to the accompanying drawings. In the present disclosure, when a first component (or an area, a layer, a part, or the like) is described as being “disposed above,” “connected to,” or “coupled to” a second component, it means that the first component may be directly connected/coupled or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the aspects. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that the term such as “includes” or “has” is intended to specify the presence of features, numbers, steps, operations, components, parts, or a combination thereof described in the disclosure and does not preclude the presence or addition possibility of one or more other features, numbers, steps, operations, components, parts, or combinations thereof in advance.

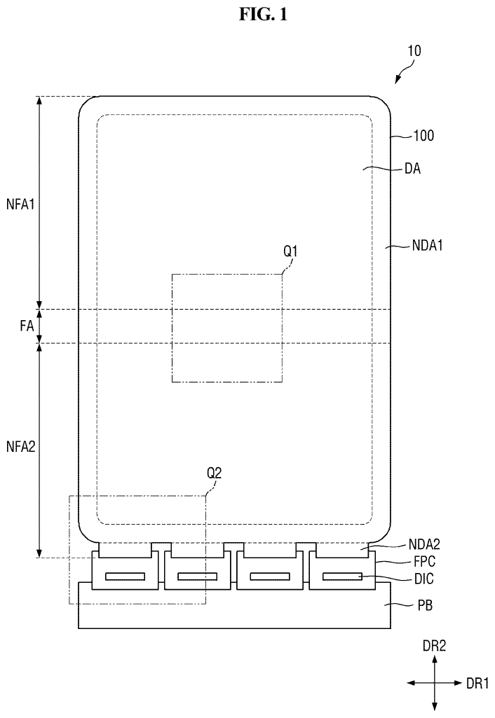

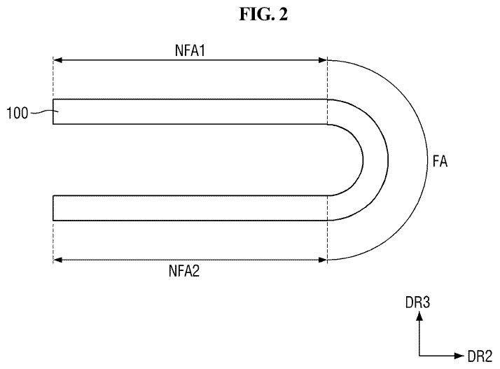

FIG. 1 is a plan view of a display device according to a first aspect. FIG. 2 is a cross-sectional view showing a folded state of the display device shown in FIG. 1.

Referring to FIGS. 1 and 2, a display device 10 according to a first aspect may be an organic light emitting diode (OLED) display, but is not limited thereto and may be a liquid crystal display (LCD) or an inorganic light emitting display. The following description will focus on a case in which the display device according to one aspect is an OLED display. The OLED display may include a display panel 100. The display panel 100 may include a display area DA and a first non-display area NDA1 positioned around the display area DA. In other words, the display area DA and the first non-display area NDA1 positioned around the display area DA may be defined in the display panel 100. All areas to be described below may be described as being included in the display panel 100 and described as being defined in the display panel 100.

The display area DA may include a plurality of pixels. The plurality of pixels may be arranged in a matrix arrangement manner, but is not limited thereto. The display area DA may have a rectangular shape including short sides extending in a first direction DR1 and long sides extending in a second direction DR2, but is not limited thereto.

The first non-display area NDA1 may surround the display area DA on a plane. For example, the first non-display area NDA1 may be disposed to surround all of the long sides (or the sides extending in the second direction DR2) and the short sides (or the sides extending in the first direction DR1) of the display area DA, but is not limited thereto.

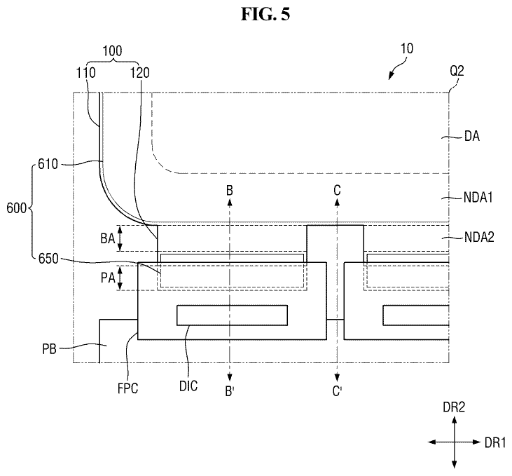

The display panel 100 may further include a second non-display area NDA2. The second non-display area NDA2 may be disposed adjacent to the first non-display area NDA1. For example, the second non-display area NDA2 may be disposed adjacent to the first non-display area NDA1 surrounding a short side positioned at the other side of the display area DA in the second direction DR2. The second non-display area NDA2 may be spaced apart from the display area DA with the first non-display area NDA1 interposed therebetween. The second non-display area NDA2 may indicate an area protruding from the first non-display area NDA1 to the other side of the display area DA in the second direction DR2. A second part 120 (see FIG. 5) may be disposed in the second non-display area NDA2. A plurality of second parts 120 may be provided. The plurality of second parts 120 (see FIG. 5) may be disposed. The plurality of second parts 120 may be spaced apart from each other in the first direction DR1.

The second non-display area NDA2 may include a pad area PA (see FIG. 5). The pad area PA may be disposed at an end portion of the other side of the second non-display area NDA2 in the second direction DR2.

A printed circuit film FPC may be attached on the pad area PA. A driving chip DIC may be mounted on the printed circuit film FPC. A plurality of printed circuit films FPCs may be provided to be attached to correspond to the plurality of second parts 120, respectively. The plurality of printed circuit films FPCs may each be attached to the corresponding pad areas PA of the second parts 120, respectively. The plurality of printed circuit films FPCs may be disposed to be spaced apart from each other in the first direction DR1. An end portion of one side of the printed circuit film FPC in the second direction DR2 may be attached to the pad area PA.

The display device 10 according to the first aspect may be a medium-sized display device. For example, the display device 10 may include a medium-sized display device such as a tablet or a monitor. In the case of the medium-sized display device, since the number of pixels is large, a plurality of printed circuit films FPC for controlling the driving of the pixels may be applied. However, the display device 10 is not limited thereto and may include a small or large-sized display device.

A circuit board PB may be attached on an end portion of the other side of the printed circuit film FPC in the second direction DR2. The plurality of printed circuit films FPCs may be connected to one circuit board PB. In FIG. 1, the one circuit board PB is shown as being connected to all of the printed circuit films FPCs of the display device 10, but is not limited thereto, and a plurality of circuit boards PB may be provided. The plurality of printed circuit films FPCs may be provided and arranged in the first direction DR1.

Although not shown on the circuit board PB, a power management IC (PMIC), a controller, and the like may be mounted thereon. The controller may perform overall control functions related to the driving of the display panel 100 and control the operation of the driving chip DIC and a gate driving circuit. The power management IC may supply various voltages or currents to the driving chip DIC, the gate driving circuit, and the like or control various voltages or currents to be supplied to the driving chip DIC, the gate driving circuit, and the like. The gate driving circuit may be exemplarily disposed on the first non-display area NDA1 at one side or the other side of the display area DA in the first direction DR1, but is not limited thereto.

Meanwhile, the display device 10 according to the first aspect may be a foldable display device. The display device 10 may include a folding area FA extending in the first direction DR1, a first non-folding area NFA1 positioned at one side of the folding area FA in the second direction DR2, and a second non-folding area NFA2 positioned at the other side of the folding area FA in the second direction DR2.

As shown in FIG. 2, the display device 10 may be folded with respect to the folding area FA. For example, when the display device 10 is folded, the first non-folding area NFA1 and the second non-folding area NFA2 may be disposed to overlap each other in a thickness direction. As will be described below, the display device 10 may be a foldable display device and at the same time, a bendable display device.

However, the present disclosure is not limited thereto, and the display device 10 may be a stretchable display device. In the present disclosure, the stretchable display device may be referred to as a display device capable of displaying images even when bent or stretched. The foldable display device and the stretchable display device may have higher flexibility than general display devices. A shape of the stretchable display device may be freely changed according to a user's manipulation, for example, by bending or stretching the stretchable display device. For example, when the user holds and pulls an end of the stretchable display device, the stretchable display device may be stretched by the user's force. Alternatively, when the user arranges the stretchable display device on an uneven wall, the stretchable display device may be disposed to be bent along a shape of a surface of the wall. In addition, when the force applied by the user is removed, the stretchable display device may return to an original shape.

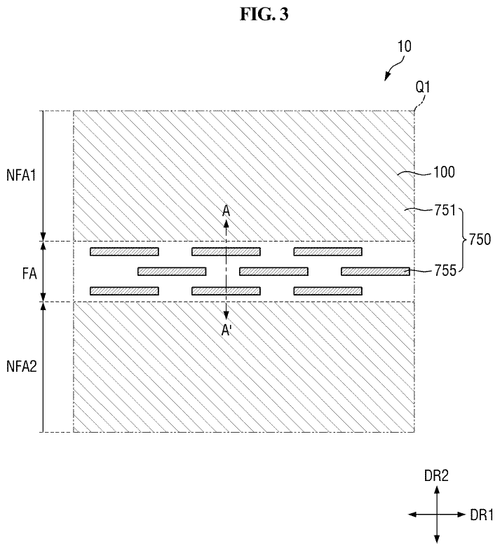

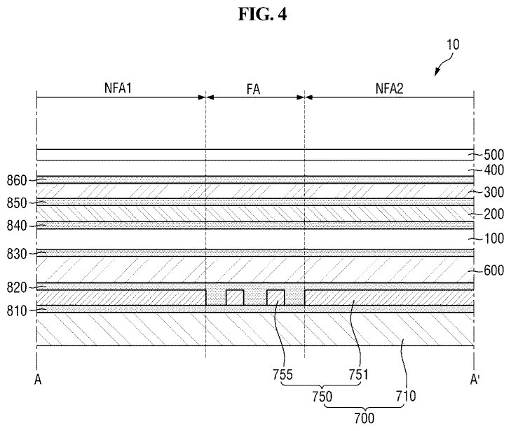

FIG. 3 is an enlarged plan view of area Q1 in FIG. 1. FIG. 4 is a cross-sectional view along line A-A′ in FIG. 3.

Referring to FIGS. 3 and 4, the display device 10 may further include a second plate layer 750 disposed under the display panel 100. The second plate layer 750 may include metal, for example, stainless steel, but is not limited thereto.

The second plate layer 750 may include plate portions 751 disposed in the first and second non-folding areas NFA1 and NFA2, and patterns 755 disposed in the folding area FA. The plate portions 751 may be spaced apart from each other with the folding area FA interposed therebetween. Each of the patterns 755 may have a line shape extending in the first direction DR1. The patterns 755 may be disposed to be spaced apart from each other. In FIG. 3, the patterns 755 are shown as arranged in three rows in the second direction DR2, but are not limited thereto. As described above, the second plate layer 750 may include metal, and to reduce a folding stress in the folding area FA when the display device 10 is folded, the second plate layer 750 may be formed of the plurality of patterns 755 in the folding area FA.

The extension direction of the pattern 755 in the first direction DR1 is related to the extension direction of the folding area FA described above in FIG. 1.

Since the folding area FA extends in the first direction DR1 and the first and second non-folding areas NFA1 and NFA2 overlap each other with respect to the folding area FA, the pattern 755 of the folding area FA may also extend in the first direction DR1 and thus function to reduce the folding stress when the display device 10 is folded.

Hereinafter, components of the display device 10 will be described in more detail with reference to FIG. 4.

Referring to FIGS. 1 to 4, the display device 10 may include a display panel 100, a polarization layer 200 disposed above the display panel 100, a cover layer 300 disposed above the polarization layer 200, a hard coating layer 500 disposed above the film layer 400, a backplate layer 600 disposed under the display panel 100, a plate layer 700 disposed under the backplate layer 600, and coupling layers 810, 820, 830, 840, 850, and 860 coupling adjacent members 100, 200, 300, 400, 600, and 700.

The display panel 100 may include a plurality of pixels disposed in a display area of a base substrate and driving units disposed in a non-display area around the display area to drive the pixels. The pixels may include transistors TFTs connected to the driving units with control signal lines, and a light emitting element OLED connected to the transistors TFTs. The transistors TFTs are turned on or off according to control signals applied through the control signal lines to adjust the amount of current applied to the light emitting element OLED. The light emitting element OLED may emit light with brightness corresponding to the amount of current applied through the transistors TFT. The light emitting element OLED may include a light emitting diode, but is not limited thereto. The base substrate may include a flexible substrate. Since the base substrate of the display panel 100 is flexible by including a flexible substrate, the display device 10 may function as a foldable, stretchable, or bendable display device.

The backplate layer 600 may be disposed under the display panel 100. The backplate layer 600 may be disposed under the display panel 100 to support the display panel 100. The backplate layer 600 may include a material capable of supporting the display panel 100. For example, the backplate layer 600 may include polyethylene terephthalate (PET), polyimide (PI), or polycarbonate (PC), but is not limited thereto.

The plate layer 700 may be disposed under the backplate layer 600. The plate layer 700 may include a first plate layer 710 and a second plate layer 720 disposed on the first plate layer 710. Each of the plate layers 710 and 720 may include metal. For example, each of the plate layers 710 and 720 may include stainless steel, but is not limited thereto. The second plate layer 750 may include the plate portions 751 disposed in the non-folding areas NFA1 and NFA2, and the patterns 755 disposed in the folding area FA. The first plate layer 710 may be disposed under the second plate layer 750 to prevent the patterns 755 from being visible.

The polarization layer 200 may be disposed above the display panel 100. The polarization layer 200 may include a first phase retardation layer, a second phase retardation layer disposed on the first phase retardation layer, and a polarization layer disposed on the second phase retardation layer. In FIG. 3, the polarization layer 200 and the display panel 100 are shown as being separated from each other, but are not limited thereto, and the polarization layer 200 may be defined as being included in the display panel 100.

The cover layer 300 may be disposed on the polarization layer 200. The cover layer 300 may be formed of glass or made of a glass material including quartz. However, the cover layer 300 is not limited thereto and may be made of a plastic material.

The cover layer 300 may be disposed above the display panel 100 to protect members disposed under the cover layer 300 from the outside. Meanwhile, since the display device 10 functions as a foldable, stretchable, or bendable display device, the cover layer 300 should have flexibility. To this end, a modulus of the cover layer 300 may be smaller than or equal to 70 GPa, and a thickness t3 may also be smaller than or equal to about 100 μm. However, when the thickness t3 of the cover layer 300 is too small, the cover layer 300 cannot function to protect the members disposed under the cover layer 300, and thus the cover layer 300 may have a thickness of at least about 20 μm or more. The cover layer 300 may be a cover layer formed by chemical reinforcement.

Meanwhile, although the cover layer 300 functions to protect the members disposed under the cover layer 300 from the outside, as described above, since the cover layer is made of a glass material, the cover layer 300 may be destroyed by an external force to generate glass fragments, and the glass fragments may scatter to the outside of the display device 10. In the first aspect, to prevent the scattering of the glass fragments generated by the destruction of the cover layer 300, the film layer 400 and the hard coating layer 500 may be further included above the cover layer 300.

The film layer 400 may function to protect the cover layer 300. The film layer 400 may be a thin film sheet made of a polymer organic material. The film layer 400 may have a high transmittance of 88% or more, heat resistance of 100° C. or higher, and a coefficient of thermal expansion of 80 e-6/K or less. This is to prevent the film layer 400 from being bent or damaged in a high-temperature, high-humidity, or thermal impact environment (e.g., in 100° C.). In other words, the film layer 400 may have a low coefficient of thermal expansion and may be made of a material with thermal stability. For example, the film layer 400 may be made of polyimide (PI), (poly) norbornene, high heat-resistant polyester (PET), epoxy, urethane, or the like. Alternatively, the film layer 400 may be made of a co-polymer. For example, the film layer 400 may be made of a copolymer combining polymethyl methacrylate (PMMA) with special PMMA, a copolymer combining polycarbonate (PC) with PI, a copolymer combining PMMA with PI, or a copolymer combining urethane. A thickness t4 of the film layer 400 may be about 75 μm or less. When the thickness t4 of the film layer 400 exceeds 75 μm, it may be difficult for the display device 10 to function as the foldable, stretchable, or bendable display device. However, only when the thickness t4 of the film layer 400 is about 25 μm or more, the film layer 400 may function to protect the cover layer 300. In other words, only when the thickness t4 of the film layer 400 is about 25 μm or more, it is possible to prevent physical destruction of the cover layer 300 and prevent scattering even when the cover layer 300 is destroyed to generate glass fragments.

A modulus of the film layer 400 may be smaller than the modulus of the cover layer 300 and may be larger than a modulus of a third coupling layer 730. For example, the modulus of the film layer 400 may be in the range of 2 GPa to 8 GPa. For example, when the modulus of the film layer 400 is 8 GPa or less, flexibility may be provided to the film layer 400 and thus the display device 10 may function as the foldable, stretchable, or bendable display device. In addition, the film layer 400 may have a modulus of 2 Gpa or more depending on the material of the film layer 400.

The hard coating layer 500 may be disposed on the film layer 400. The hard coating layer 500 may be formed by being coated directly on an upper surface of the film layer 400. Since the hard coating layer 500 touches a front surface of the cover layer 300, the hard coating layer 500 may be implemented as a surface protective layer with more reinforced strength, and when the hard coating layer 500 is used as the surface protective layer, the hard coating layer 500 uses a material with a high content of a resin with a relatively high hardness when cured, for example, a resin such as acrylic or epoxy. In addition, the hard coating layer 500 may be given an anti-finger (AF) or anti-reflective (AR) function as needed, may be implemented by synthesizing a resin having these functions, or implemented by forming various patterns, for example, patterns such as moth eye.

The coupling layers 810 to 860 may include a first coupling layer 810 for coupling the first plate layer 710 with the second plate layer 750, a second coupling layer 820 for coupling the second plate layer 750 with the back plate layer 600, a third coupling layer 830 for coupling the back plate layer 600 with the display panel 100, a fourth coupling layer 840 for coupling the display panel 100 with the polarization layer 200, a fifth coupling layer 850 for coupling the polarization layer 200 with the cover layer 300, and a sixth coupling layer 860 for coupling the cover layer 300 with the film layer 400.

Each of the coupling layers 810 to 860 may include an optically transparent resin (OCR) or an optically transparent adhesive (OCA).

Hereinafter, the second non-display area NDA2, the printed circuit film FPC, and the circuit board PB of the display device 10 according to the first aspect will be described in detail.

FIG. 5 is an enlarged plan view of area Q2 in FIG. 1.

Referring to FIGS. 1 to 5, the display panel 100 may include the first part 110 disposed in the display area DA and the first non-display area NDA1, and the second parts 120 disposed in the second non-display area NDA2. Each of the second parts 120 may protrude from the first part 110 to the other side in the second direction DR2. The second parts 120 may be spaced apart from each other in the first direction DR1. The printed circuit film FPC may be attached to the pad area PA of the second part 120. The pad area PA may be spaced apart from the first non-display area NDA1 with a bending area BA interposed therebetween. Each of the second parts 120 may be bent in the bending area BA.

The backplate layer 600 may include a first backplate layer 610 and a second backplate layer 650. The first backplate layer 610 may be disposed in the display area DA and the first non-display area NDA1. The first backplate layer 610 may overlap the first part 110 of the display panel 100 and may have the same area as the first part 110, but is not limited thereto. The second backplate layer 650 may be spaced apart from the first backplate layer 610 with the bending area BA interposed therebetween. The second backplate layer 650 may be disposed in the second non-display area NDA2. The second backplate layer 650 may be disposed in the second non-display area NDA2 except for the bending area BA. Since the backplate layer 600 is not disposed in the bending area BA, it is possible to reduce the bending stress when the second part 120 of the display panel 100 is bent.

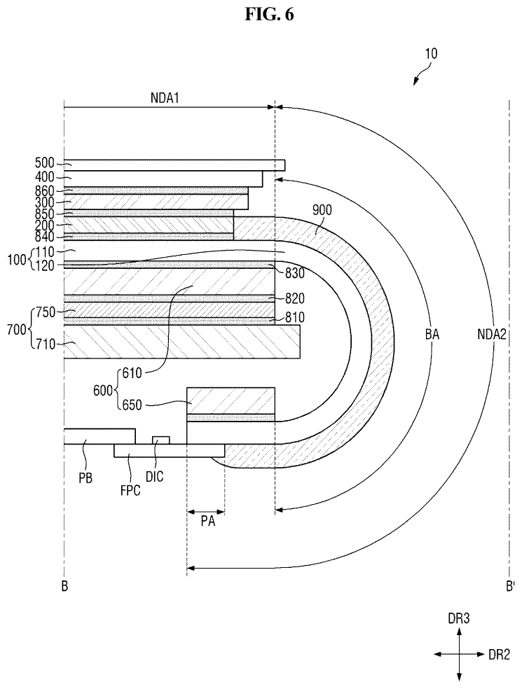

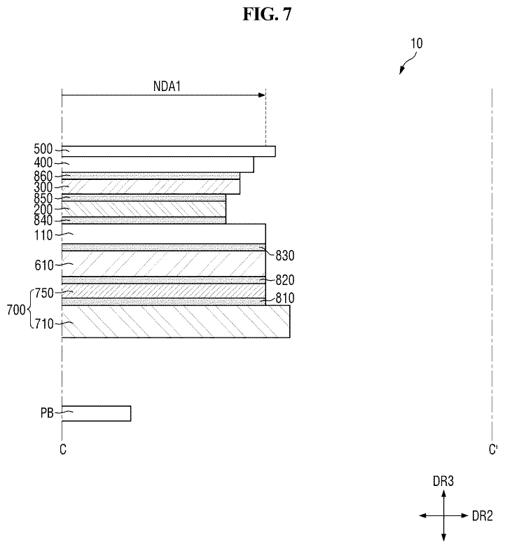

FIG. 6 is a cross-sectional view along line B-B′ in FIG. 5. FIG. 6 shows a cross-sectional view of the display panel 100 of FIG. 5 when bent. In other words, FIG. 6 shows a case in which the second part 120 of the display panel 100 is bent about the bending area BA. FIG. 7 is a cross-sectional view along line C-C′ in FIG. 5. The cross-sectional view of FIG. 7 differs from the cross-sectional view of FIG. 6 in that it does not include the second non-display area NDA2.

Referring to FIGS. 5 to 7, the second part 120 may be bent in the bending area BA. In FIG. 6, the bending area BA is shown as being directly connected to the first non-display area NDA1, but the bending area BA may be spaced a predetermined distance from the first non-display area NDA1. In this case, the second part 120 may have a structure which extends flat in the second direction DR2 like the first non-display area NDA1 and then is bent in the bending area BA. The second part 120 may be bent in the bending area BA and then may extend flat to the other side in the second direction DR2. The pad area PA of the second part 120 may extend flat and overlap the first non-display area NDA1 in the thickness direction.

The printed circuit film FPC may be attached to the pad area PA of the second part 120.

The first backplate layer 610 may be disposed in the first non-display area NDA1. The second backplate layer 650 may be disposed between the pad area PA of the second part 120 and the first backplate layer 610. The backplate layers 610 and 650 may be attached to the first part 110 and the second part 120, respectively, through the third coupling layer 830. The backplate layers 610 and 650 may not be disposed in the bending area BA.

The second plate layer 750 may overlap the first backplate layer 610 and may be disposed between the first backplate layer 610 and the first plate layer 710. The second plate layer 750 may be disposed only in the first non-display area NDA1 and may not be in the second non-display area NDA2. A portion of an end portion of the first plate layer 710 may extend to the second non-display area NDA2. In other words, the end portion of the first plate layer 710 may protrude toward the bending area BA more than an end portion of the second plate layer 750 or an end portion of the first back plate layer 610. The second plate layer 750 may be attached to the first backplate layer 610 through the second coupling layer 820. The first plate layer 710 may be attached to the second plate layer 750 through the first coupling layer 810.

An end portion of the polarization layer 200 may be positioned inside the first non-display area NDA1. The polarization layer 200 may expose the first part 110 at an end portion of the first non-display area NDA1. The polarization layer 200 may be attached to the first part 110 through the fourth coupling layer 840.

Meanwhile, a protective layer 900 may be further disposed on an upper surface of the second part 120. The protective layer 900 may be disposed on the upper surface of the second part 120 to reduce the bending stress of the bending area BA of the second part 120. The protective layer 900 may include an organic material. The protective layer 900 may be in contact with side surfaces of the polarization layer 200 and the third coupling layer 730. The protective layer 900 may be in contact with the printed circuit film FPC and may cover a portion of the upper surface (indicating the upper surface before bending) of the printed circuit film FPC.

The end portion of the cover layer 300 may extend toward the bending area BA more than the end portion of the polarization layer 200, but is not limited thereto.

The end portion of the film layer 400 may extend toward the bending area BA more than the end portion of the cover layer 300, but is not limited thereto.

An end portion of the hard coating layer 500 may extend toward the bending area BA more than the end portion of the film layer 400, but is not limited thereto. A portion of the hard coating layer 500 may be disposed in the bending area BA, but is not limited thereto.

Hereinafter, problems caused by the movement of the second parts 120 of the display panel 100 of the display device 10 according to the first aspect will be described.

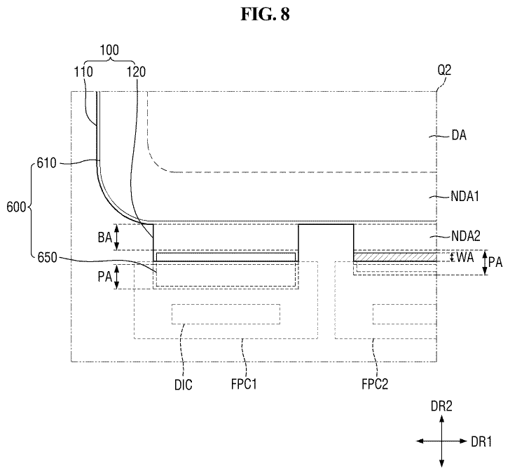

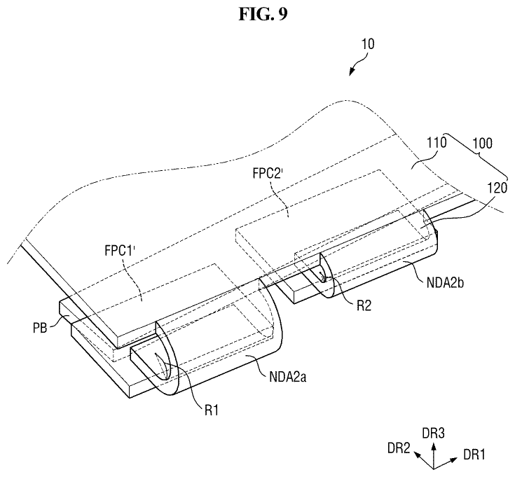

FIG. 8 is a schematic view showing attachment deviation between printed circuit films of the display device according to the first aspect. FIG. 9 is a schematic view showing attachment deviation of a circuit board of the display device according to the first aspect.

FIG. 8 shows a process of attaching a plurality of printed circuit films FPC1 and FPC2 to the corresponding second parts 120, respectively. The process of attaching the plurality of printed circuit films FPC1 and FPC2 to the corresponding second parts 120, respectively may be performed in a state in which the second parts 120 are unfolded flat.

As shown in FIG. 8, the second parts 120 of the display device 10 according to the first aspect are spaced apart from each other and may not be directly connected. In other words, the second parts 120 may be in a state of being directly connected to the first part 110 but being not connected. In this case, a wavemess area may be generated in at least one of the second parts 120. FIG. 8 shows that a wavemess area WA has been generated in the second part 120 positioned at the right side. On the other hand, the second part 120 positioned at the left may be in a state of being unfolded flat.

As shown in FIG. 8, the printed circuit films FPC1 and FPC2 may be attached to the corresponding second parts 120, respectively, at the same position, and as described above, since the second part 120 positioned at the right side includes the wavemess area WA, the pad area PA of the second part 120 positioned at the right side is positioned at one side in the second direction DR2 compared to the pad area PA of the second part 120 positioned at the left side. In this case, when the printed circuit films FPC1 and FPC2 are attached, the printed circuit film FPC1 may be attached at an accurate position to cover the pad area PA of the second part 120 positioned at the left side, but the printed circuit film FPC2 is not accurately attached to the pad area PA of the second part 120 positioned at the right side, and attachment deviation may occur. For example, as shown in FIG. 8, the printed circuit film FPC2 may not cover the pad area PA and may be attached to expose a portion of the pad area PA. In other words, alignment miss may occur between the printed circuit film FPC2 attached to the second part 120 positioned at the right side and the pads of the pad area PA of the second part 120.

FIG. 9 shows a case in which the second parts 120 of the display panel 100 of the display device 10 according to the first aspect are bent with different radii of curvature R1 and R2. As shown in FIG. 9, the second part 120 at the other side in the first direction DR1 may be bent to a first radius of curvature R1, and the second part 120 at one side in the first direction DR1 may be bent to a second radius of curvature R2 which is smaller than the first radius of curvature R1. The second parts 120 of the display panel 100 are bent with different radii of curvature R1 and R2 because the second parts 120 are each directly connected to the first part 110 but are not connected as described above. FIG. 9 schematically shows only the display panel 100, printed circuit films FPC1′ and FPC2′, and the circuit board PB to show bending of the second parts 120 of the display panel 100.

FIG. 9 shows a case in which the printed circuit films FPC1′ and FPC2′ are accurately attached to the corresponding second parts 120, respectively. In other words, the printed circuit films FPC1′ and FPC2′ may be attached at accurate positions to cover the pad area PA of each of the corresponding second parts 120. However, the present disclosure is not limited thereto, and the printed circuit films FPC1′ and FPC2′ may not cover the pad area PA of each of the corresponding second parts 120, and attachment deviation may occur to expose a portion of the pad area PA. In FIG. 9, for convenience of description, the description will focus on a case in which the printed circuit films FPC1′ and FPC2′ are accurately attached to the corresponding second parts 120, respectively.

As shown in FIG. 9, even when the printed circuit films FPC1′ and FPC2′ are accurately attached to the corresponding second parts 120, respectively, the second parts 120 are bent with different radii of curvature R1 and R2, and thus the circuit board PB attached to the other ends of the printed circuit film FPC1′ and FPC2′ may be disposed by being tilted as shown in FIG. 9. In the present disclosure, although a member to which the circuit board PB is attached is not shown, the circuit board PB may be attached to a lower surface of the first plate layer 710 or attached to a separate member. For example, as shown in FIG. 9, when the circuit board PB is tilted and attached to the first plate layer 710 or a separate member, twist occurs inside the circuit board PB, thereby not only causing physical damage to the circuit board PB but also causing unexpected physical interference with other components at the attached position.

Hereinafter, a second aspect for solving the problems of the display device 10 according to the first aspect will be described.

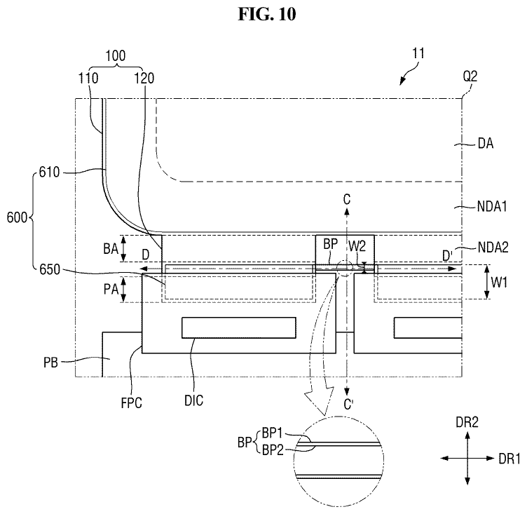

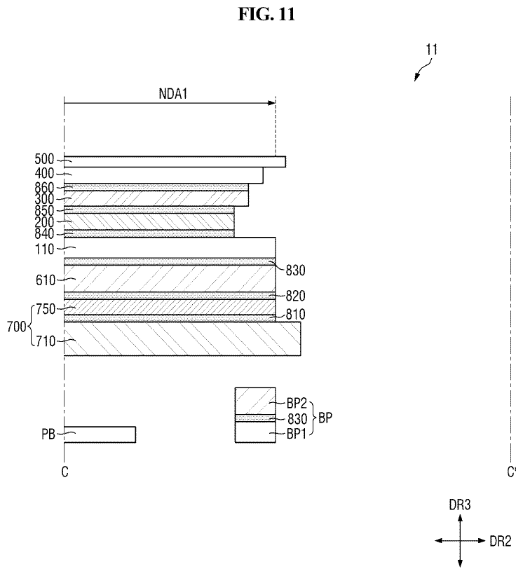

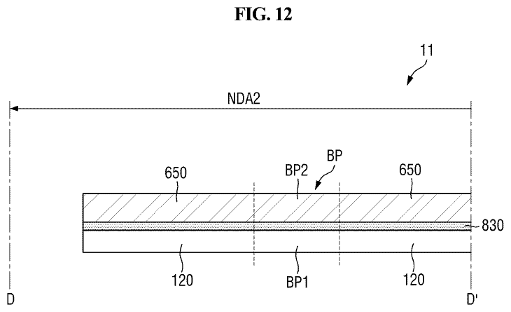

FIG. 10 is a plan view of a display device according to a second aspect. FIG. 11 is a cross-sectional view along line C-C′ in FIG. 10. FIG. 12 is a cross-sectional view along line D-D′ in FIG. 10.

Referring to FIGS. 10 to 12, a display device 11 according to the second aspect differs from the display device 10 shown in FIGS. 5 to 7 in that it further includes a bridge part BP.

More specifically, the display device 11 may further include the bridge part BP for connecting adjacent second parts 120. The bridge part BP may be disposed between the adjacent second parts 120 on a plane and physically connected to each of the second parts 120. The bridge part BP may include a first bridge part BP1 and a second bridge part BP2 which overlap each other in the thickness direction. The second bridge part BP2 may be disposed on the first bridge part BP1. A width W2 of the bridge part BP in the second direction DR2 may be smaller than a width W1 of the second part 120 (or the second non-display area NDA2) in the second direction DR2 except for the bending area BA. Meanwhile, since the second part 120 shown in FIG. 10 is in an unfolded state without being bent, it should be noted that comparison between the width W2 of the bridge part BP in the second direction DR2 and the width W1 of the second part 120 (or the second non-display area NDA2) in the second direction DR2 except for the bending area BA is made in the unfolded state of the second part 120. Furthermore, even when the second part 120 is bent, a width of the bridge part BP measured in a bending direction may be smaller than the width of the second part 120 (or the second non-display area NDA2) in the second direction DR2 except for the bending area BA.

The first bridge part BP1 may connect adjacent second parts 120, and the second bridge part BP2 may connect adjacent second backplate layers 650. The first bridge part BP1 and the second bridge part BP2 may be coupled through the third coupling layer 830. The first bridge part BP1 may be disposed on the same layer as the second part 120, and the second bridge part BP2 may be disposed on the same layer as the second backplate layer 650.

The first bridge part BP1 and the second bridge part BP2 may have the same shape and area.

The second parts 120 of the display device 11 according to the second aspect are spaced apart from each other, but may be directly connected through the bridge part BP. For example, the second parts 120 may be directly connected through the first bridge part BP1 of the bridge part BP. Therefore, in the case of the display device 11, since the second parts 120 are integrally connected, it is possible to improve the phenomenon in which the wavemess area is generated in at least one of the second parts 120 shown in FIG. 8.

In other words, in the process of attaching the printed circuit films FPC to the corresponding second parts 120, respectively, at the same position, the printed circuit films FPC are attached at the accurate positions to cover the pad areas PA of the corresponding second parts 120, respectively.

It is possible to prevent the occurrence of the alignment miss between the printed circuit film FPC and the pads of the pad area PA of the second part 120.

In addition, as described above with reference to FIG. 9, it is possible to solve the problem that the second parts 120 are bent with different radii of curvature R1 and R2. In other words, in the case of the display device 11, since the second parts 120 are integrally connected, all of the second parts 120 may be bent with the same radius of curvature. As a result, the circuit board PB attached to the other end of each of the printed circuit films FPCs may not be tilted. Therefore, it is possible to not only solve the problem that the physical damage to the circuit board PB is caused by the occurrence of twist inside the circuit board PB, but also prevent the occurrence of unexpected physical interference with other components at the attached position.

Although the aspects have been described above with reference to the accompanying drawings, those skilled in the art to which the present disclosure pertains will be able to understand that the above-described technical configuration may be carried out in other specific forms without changing the technical spirit or essential features thereof. Therefore, it should be understood that the above-described aspects are illustrative and not restrictive in all respects. In addition, the scope of the aspects is indicated by the claims to be described below rather than the detailed description. In addition, the meaning and scope of the claims and all changed or modified forms derived from the equivalent concept thereof should be construed as being included in the scope of the aspects. Thus, it is intended that the present disclosure covers the modifications and variations of the aspects provided they come within the scope of the appended claims and their equivalents.

What is claimed is:

1. A display device comprising:
a display panel including a display area, a first part positioned around the display area and including a first non-display area, and second parts disposed in a second non-display area positioned outside the first non-display area; and
a bridge part disposed between adjacent second parts,
wherein the second parts are spaced apart from each other in a first direction,
each of the second parts protrudes from the first part in a second direction intersecting the first direction, and
the bridge part physically connects the adjacent second parts.

2. The display device of claim 1, wherein the second non-display area includes a bending area, and a pad area spaced apart from the first non-display area with the bending area interposed therebetween, the second part is bent in the bending area, and the pad area overlaps the first non-display area.

3. The display device of claim 2, further comprising printed circuit films having one end connected to the pad area, wherein the printed circuit films are connected to the second parts, respectively.

4. The display device of claim 3, further comprising a circuit board connected to another end of the printed circuit films.

5. The display device of claim 2, wherein the bridge part includes a first bridge part positioned at a same layer as the display panel.

6. The display device of claim 5, further comprising a back plate layer disposed under the display panel, wherein the back plate layer includes a first back plate layer disposed on the display area and the first non-display area, and a second back plate layer disposed on the pad area.

7. The display device of claim 6, wherein the second back plate layer is disposed between the pad area of the display panel and the first back plate layer.

8. The display device of claim 6, wherein the bridge part further includes a second bridge part overlapping the first bridge part and positioned on a same layer as the back plate layer.

9. The display device of claim 1, further comprising a plate layer disposed under the display panel and overlapping the first part.

10. The display device of claim 9, wherein the display panel includes a folding area extending in the first direction, a first non-folding area positioned at one side of the folding area in the second direction, and a second non-folding area positioned at another side of the folding area in the second direction.

11. The display device of claim 10, wherein the plate layer includes a first plate layer, and a second plate layer disposed above the first plate layer, and the second plate layer includes patterns disposed in the folding area.

12. A display device comprising:
a display panel including a first part, and second parts protruding from the first part and including a bending area; and
a bridge part disposed between adjacent second parts,
wherein the second parts are spaced apart from each other in a first direction,
each of the second parts protrudes from the first part in a second direction intersecting the first direction,
the second part is bent in the bending area, and
radii of curvature of the second parts are the same.

13. The display device of claim 12, wherein the second part includes a pad area spaced apart from the first part with the bending area interposed therebetween, and the pad area overlaps the first part.

14. The display device of claim 13, further comprising printed circuit films having one end connected to the pad area, wherein the printed circuit films are connected to the second parts, respectively.

15. The display device of claim 14, further comprising a circuit board connected to another end of the printed circuit films.

16. The display device of claim 13, wherein the bridge part includes a first bridge part positioned at a same layer as the display panel.

17. The display device of claim 16, further comprising a back plate layer disposed under the display panel, wherein the back plate layer includes a first back plate layer overlapping the first part, and a second back plate layer disposed on the pad area.

18. The display device of claim 17, wherein the second back plate layer is disposed between the pad area of the display panel and the first back plate layer.

19. The display device of claim 17, wherein the bridge part further includes a second bridge part overlapping the first bridge part and positioned on a same layer as the back plate layer.

20. The display device of claim 12, further comprising a plate layer disposed under the display panel and overlapping the first part,
wherein the display panel includes:
a folding area extending in the first direction;
a first non-folding area positioned at one side of the folding area in the second direction; and
a second non-folding area positioned at the other side of the folding area in the second direction,
wherein the plate layer includes a first plate layer, and a second plate layer disposed above the first plate layer, and the second plate layer includes patterns disposed in the folding area.
